(19) United States
(12) Patent Application Publication
(10) Pub. No.: US 2008/0273390 A1
(43) Pub. Date: Nov. 6, 2008

(54) NAND flash memory cell array and method of fabricating the same

(75) Inventors: Chung-We Pan, Pingtung (TW); Henry Chang, Hsinchu (TW); Tzeng-Wen Tzeng, Taoyuan (TW); Ching-Hung Fu, Hsinchu (TW); Chih-Ping Chung, Hsinchu (TW)

Correspondence Address: BIRCH STEWART KOLASCH & BIRCH, PO BOX 747, FALLS CHURCH, VA, 22040-0747, US

(73) Assignee: ProMOS Technologies Inc.

(21) Appl. No.: 11/797,613

(22) Filed: May 4, 2007

(51) Int. Cl. G11C 11/34; H01L 21/82

(52) U.S. Cl. 365/185.17; 438/129; 257/E27.004

(57) ABSTRACT

A novel NAND flash memory cell array and the method of fabricating the same are disclosed in this invention. The NAND flash memory cell array comprises a substrate with an active area; a plurality of cells arranged in a row on the active area; a first barrier layer covering the cells and the active area around each end of the row; a first oxide deposited to fill a gap between the cells; an oxide spacer formed along the sidewall of a cell located at each end of the row; and a poly spacer formed on the oxide spacer acting as a selection gate for driving the row of cells. The aspect ratio of the gap between the cells is about 1.8 to 3.2. Many advantages are provided with such NAND flash memory fabricating by the self-aligned process of the present invention.

### BACKGROUND OF THE INVENTION

1. Field of the Invention

The present invention relates to a semiconductor process of fabricating a NAND flash memory and more particularly, to a method for fabricating a NAND flash memory with a self-aligned process.

2. Description of the Related Art

A flash memory has the benefits of small volume, power saving, high speed, fine tolerance and low operating voltage. Thus, flash memory has become a crucial component for products such as digital cameras, cell-phones, printers and PDAs, etc. A NAND-type flash memory is one type of flash memory. Cells of the NAND-type flash memory are connected to each other and arranged in the form of an array, in which only the first one cell and the last one cell of a row of an array are respectively connected to a word line and a bit line. With such architecture, the NAND-type flash memory can save more data than NOR flash memory. This means that the NAND flash memory has a larger memory capacity and a faster rewriting speed. The NAND flash memory is widely used to store bulk data and is implemented as the memory card for digital cameras and MP3 players.

Shin et al. in U.S. Pat. No. 6,936,885 disclosed NAND-type flash memory devices and method of fabricating the same. FIG. 1a is a top plan view showing a portion of the cell array region of a NAND-type flash memory device. FIG. 1b is a cross-sectional view illustrating a flash memory device along the line I-I of the FIG. 1a. Referring now to FIG. 1a and FIG. 1b, a string selection line pattern 1s and a ground selection line pattern 1g are essential for defining the string selection transistor 13 and the ground selection transistor 19. A plurality of cell transistors, 15 and 17, is formed on the regions where the active areas 2 intersect with the word line WP1˜WPn. The string selection transistor 13 and the ground selection transistor 19 are used to drive the row of cell transistors 15 and 17. Due to this particular structure and the two selection transistors 13 and 19, the complexity of the manufacturing process is increased. Moreover, one problem with this prior art is that the patterns 1s and 1g that define the selection transistors 13 and 19 are required to have a high precision. This high precision prerequisite will inevitably increase the manufacturing cost.

Chen et al. in U.S. Pat. No. 6,885,586 disclosed a self-aligned split-gate NAND flash memory and method of fabricating the same. By first depositing a conductive layer with doped polysilicon or polycide and then etching said layer anisotropically, the selection gates for driving a row of NAND flash memory cells are formed. One problem with this structure is that the gap width between the cells is too large. This makes it difficult to decrease the size of the NAND flash memory.

There is a need to develop a novel structure of NAND flash memory cell array and the process of manufacturing the same which can address issues such as high cost and complex manufacturing process existed in the prior arts.

### SUMMARY OF THE INVENTION

One object of the present invention is to reduce the number of pattern masks and to downgrade the needs to define the selection transistors in a NAND flash memory cell array in order to control the manufacturing cost.

Another object of the present invention is to decrease the gap width between NAND flash memory cells, such that the size of the chip can be substantially reduced and the component density of the chip can be increased.

A NAND memory cell array is disclosed in the present invention which comprises: a substrate with an active area; a plurality of cells arranged in a row on the active area; a first barrier layer covering the cells and the active area around each end of the row; a first oxide deposited to fill a gap between the cells; an oxide spacer formed along the sidewall of a cell located at each end of the row; and a poly spacer formed with a self-aligned process on said oxide spacer acting as a selection gate for driving the row of cells.

Preferably, the aspect ratio of the gap between the cells is about 1.8 to 3.4.

Preferably, a first oxide with excellent step coverage can be used to fill the gap between the cells without void. According to one embodiment, a material with low step coverage can also be adopted to only seal the gap.

In one embodiment, the NAND flash memory cell array further comprises an implantation area formed by implanting predetermined ions into the active area at each end of the row; an oxide deposited on the poly spacer, the oxide spacers, the partial first barrier layer and the first oxide; a second barrier layer deposited on the second oxide; an interlayer dielectric layer deposited on the second barrier layer and on the active area around each end of the row; a contact plug formed by depositing a plug material on an opening at each end of the row and planalizing the plug material by using a Chemical Mechanical Polishing (“CMP”) process; a metal line formed at each end of the row; and an intermetal layer formed between different metal lines Furthermore, both the first barrier layer and the second barrier layer may preferably be made of nitride or thin oxynitride.

Preferably, the metal line is made of aluminum-copper alloy or the like

In another embodiment, after the metal line is formed, an intermetal layer is deposited to avoid electrical interconnection between the conductive components.

Moreover, the invention also discloses a process of fabricating the NAND flash memory cell array described above. The process includes the steps of: forming a plurality of cells arranged in a row on an active area of a substrate; depositing a first barrier layer to cover the cells and the active area around each end of the row; depositing a first oxide to fill a gap between the cells; forming an oxide spacer along the sidewall of a cell located at each end of the row; and forming a poly spacer on said oxide spacer.

In one embodiment, after the step of forming the oxide spacer along the sidewall of a cell located at each end of the row, further comprising the steps of performing a pre-clean process and then performing a TNOX oxidation.

In another embodiment, the process further comprises the steps of: stripping a portion of the first barrier layer and implanting predetermined ions into the active area near each end of the row; forming a second oxide to overlay the substrate; forming a second barrier layer on the second oxide by depositing an interlayer dielectric layer on the substrate; forming a contact plug at each end of the row; and forming a metal line on the contact plug.

In one embodiment, each metal line is connected to a conductive pad. In another embodiment, however, metal lines of the NAND flash memory cell array can be connected to a conductive trench.

A more simplified structure and a higher aspect ratio, combining with the self-aligned process, render the present invention more valuable with many advantages over the prior arts.

### BRIEF DESCRIPTION OF THE DRAWINGS

The objects and advantages of the present invention will be apparent from the following detailed description of the preferred embodiments with references to the following drawings:

FIG. 1a illustrates a top plan view showing a portion of cell array region of a NAND-type flash memory device in a prior art;

FIG. 1b illustrates a cross-sectional view illustrating a NAND-type flash memory structure in the prior art along the line I-I of the FIG. 1a;

FIG. 2a illustrates a layout of the present invention with a Self-Aligned-Shallow Trench Isolation Technology (“SA-STI Technology”) according to one embodiment of the invention.

FIG. 2b illustrates a layout of the present invention with a SA-STI Technology according to another embodiment.

FIG. 3a illustrates a layout of a NAND flash memory cell array with Self-Aligned Poly Technology (“SAP Technology”) according to one embodiment of the present invention.

FIG. 3b, illustrates a layout of two types of NAND flash memory cell array with SAP Technology according to another embodiment of the invention.

FIGS. 4a-4h are cross-sectional views illustrating the detail processes of fabricating a NAND flash memory cell array along the line A-A′ of any one of FIGS. 2a, 2b, 3a, and 3b.

### DETAILED DESCRIPTION OF THE EMBODIMENT(S)

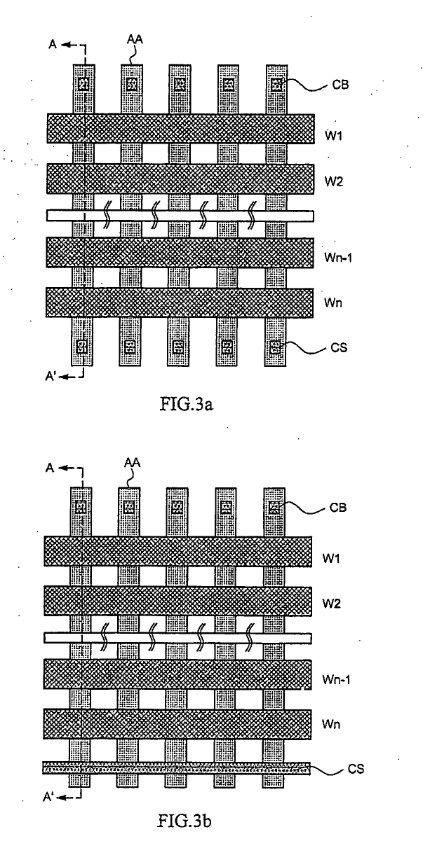

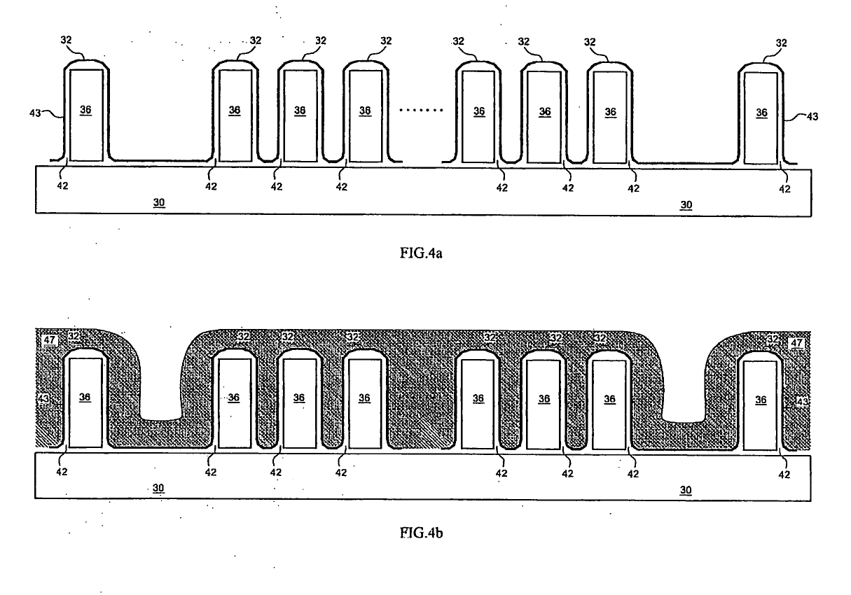

FIG. 2a and FIG. 2b illustrate the layouts formed by the SA-STI Technology of the present invention. Each of the layouts labeled as “W1˜Wn” is used to define the word lines on the substrate. The layout marked as “AA” is used to define the active areas on the substrate, and the layout marked as “FP” is used to define a plurality of floating poly layers (not shown). Moreover, the layout of “CB” defines the bit-line contacts, and the layout of “CS” defines the source line contacts on the substrate. A plurality of NAND flash memory cells is formed on where the layout “AA” intersects with any of the layouts “W1˜Wn”; and the cells are arranged in a form of an array. The operation of the NAND flash memory cells is controlled by applying voltages to bit-line contacts, common source contacts, array gate layers and selection gates (not shown). Note that each of the source line contacts is connected to a metal line.

In another embodiment illustrated by FIG. 2b, the source line contacts are connected to a conductive trench. This configuration leads to low resistance and a simplified fabrication process.

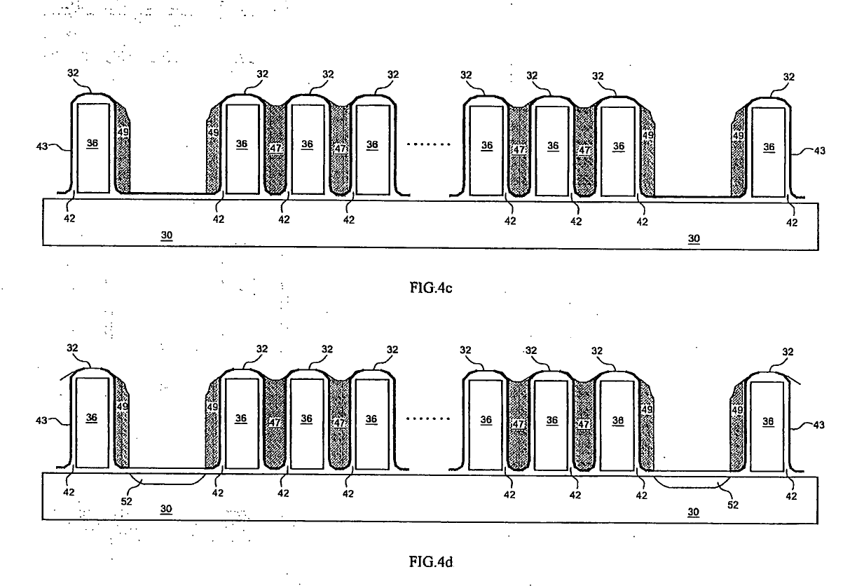

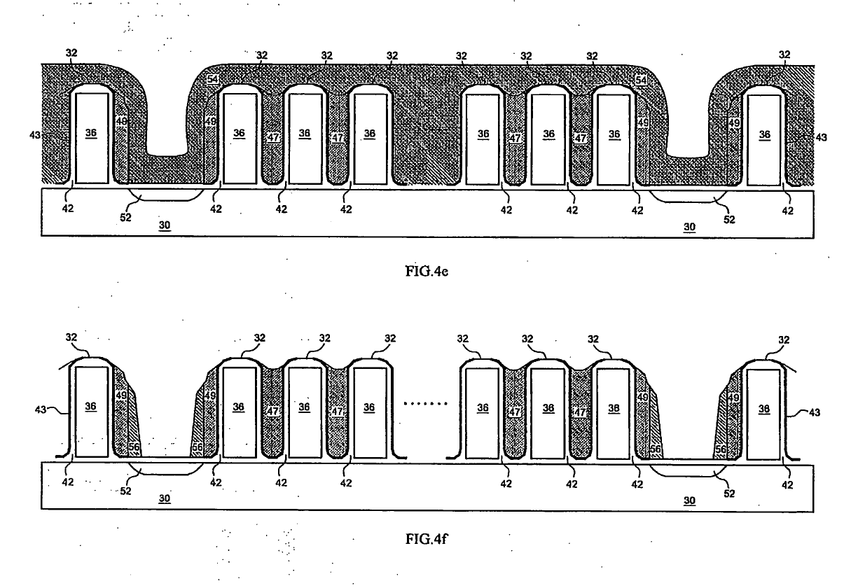

FIG. 3a and FIG. 3b illustrate the layouts of two types of NAND flash memory cell array formed by the SAP Technology. Each of the source line contacts in FIG. 3a is in a form of a metal line, and the source line contact in FIG. 3b is in a form of a trench. Comparing FIG. 3a with FIG. 2a, notice the difference is the absence of the layout FP. In FIG. 2a, with the SA-SAI Technology, the floating poly layer defined by the layout FP is used for the isolation between the rows of NAND flash memory cells. When adopting 0.1 um (or below 0.1 um) process technology to fabricate the NAND flash memory cell array, the layout FP is removed from the design rule to simplify the fabrication process and to avoid misalignment during the photo stage. In FIG. 3a, with the SAP Technology, the floating poly layer is first deposited and then removed by a CMP process. The number of masks required for defining the NAND flash memory structure is therefore reduced.

Furthermore, note that the NAND flash memory structure described above is located on a single block. With such configuration repeated on the chip, the layout CB and the layout CS are located between two blocks.

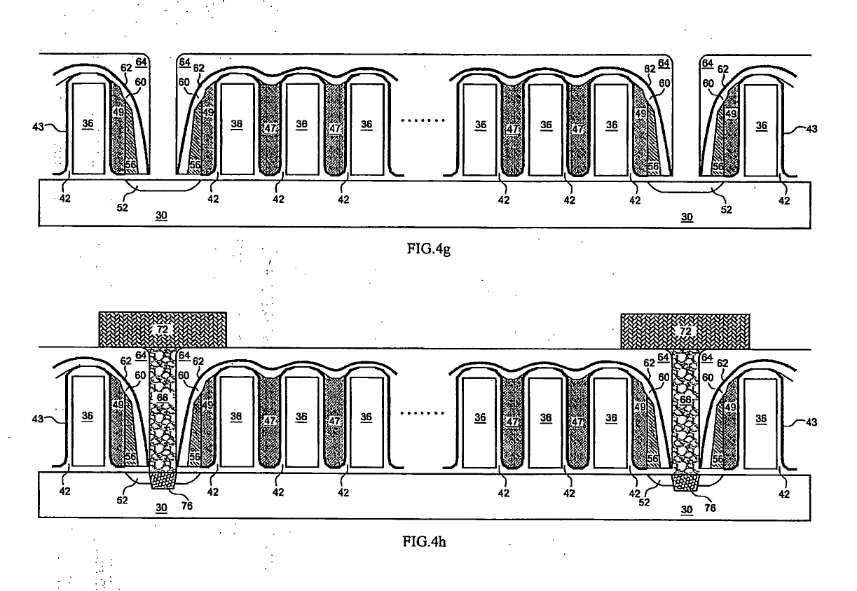

Referring now to FIG. 4a, a plurality of cells 32 is arranged in a row on a substrate 30. First, the active area structure is formed by using the SA-STI or the SAP Technology. After performing the etching process for the floating polysilicon gate (not shown in the figure), a stack of gate layers is formed on the substrate 30. By performing a photolithographic and dry-etching process, a plurality of access polysilicon gates 36 is formed on the substrate 30.

Thereafter, an ion implantation process is performed to adjust the source/drain characteristics of cells 32 and the selection transistors. Furthermore, an oxide layer 42 and a first barrier layer 43 are deposited in succession on the substrate 30 and on the access polysilicon gates 36. The oxide layer 42 is usually a layer of thin oxide. The first barrier layer 43 is usually a layer of thin nitride or thin oxynitride which is formed by performing a Remote Plasma Chemical Vapor Deposition (“RPCVD”) process or a Plasma Enhancement Chemical Vapor Deposition (“PECVD”) process on the oxide layer 42 to a thickness of about 50 to 150 Angstroms. Note that the etching selectivity of the first barrier layer 43 to the oxide layer 42 is high enough to allow an etching-back process.

Referring now to FIG. 4b, by performing a High Density Plasma Chemical Vapor Deposition (“HDP-CVD”) process or the like, an oxide layer 47 is deposited to a thickness of about 1500 to 5000 Angstroms to fill the gaps between cells 32, and on the active area around each end of the row. As shown in FIG. 4c, an etching-back process is performed to form an oxide spacer 49 on the sidewall of the cell located at each end of the row. The gaps between the cells 32 are still filled with the oxide layer 47. During the etching-back process, the first barrier layer 43 serves as an etching stop layer. According to a preferred embodiment, the oxide layer 47 with excellent step coverage can fill the gaps between the cells without void. Instead of completely filling the gaps with the oxide layer 47, a material with low step coverage can also be adopted to only seal the gaps.

According to a preferred embodiment, the aspect ratio of the gaps between the cells 32 is about 1.8 to 3.6. Controlling the aspect ratio is especially helpful in increasing the component density of a chip.

As shown in FIG. 4d, a wet etching process or a dry etching process is performed to strip the exposed first barrier layer 43. Subsequently, an ion implantation process is preformed to adjust the threshold voltage of the forthcoming selection transistor. An implantation area 52 is formed at each end of the row.

Following a pre-clean process and then a TNOX oxidation, a poly spacer is employed as the gate of the selection transistor. As shown in FIG. 4e and FIG. 4f, the poly spacers 56 is formed by first depositing a polysilicon layer 54 to a thickness of about 1200 to 3200 Angstroms. Thereafter, an etching-back process is performed to anisotropically etch the polysilicon layer 54 to form the poly spacer 56 on the sidewall of the cells 32 located at each end of the row. A layer of thin oxide 60 is then deposited over the substrate 30. Thereafter, a layer of nitride 62 serving as a barrier layer is formed on the thin oxide 60.

As shown in FIG. 4g, by using the LPCVD, the Plasma Enhancement CVD (“PECVD”) or other similar processes, an interlayer dielectric layer 64 is deposited. Afterwards, a CMP process is performed to planalize the interlayer dielectric layer 64. Subsequently, the bit-line contacts and source/drain contacts are opened by performing a photolithographic process and an anisotropical etching process. Thereafter, an ion implantation process is carried out to form the ohmic contact 76. The contact plugs 66 are applied to fill the openings defined by bit-line contacts and source/drain contacts. The contact plugs 66 are formed by first depositing a plug material such as polysilicon or tungsten, and then planalizing the plug material by using the CMP process.

Referring then to FIG. 4h, by using a PVD or other similar processes, a conductive layer made of aluminum-copper alloy or the like is deposited on both the contact plug 66 and the interlayer dielectric layer 64. Afterwards, by using a photolithography process and an etching process, the metal line 72 is formed on the contact plug 66.

In one embodiment, after the metal lines 72 is formed, an intermetal layer (not shown) is deposited to avoid the electrical interconnection between the conductive components in the cell array.

According to the aforesaid description, the metal lines 72 will be located between two blocks of the NAND flash memory cell array.

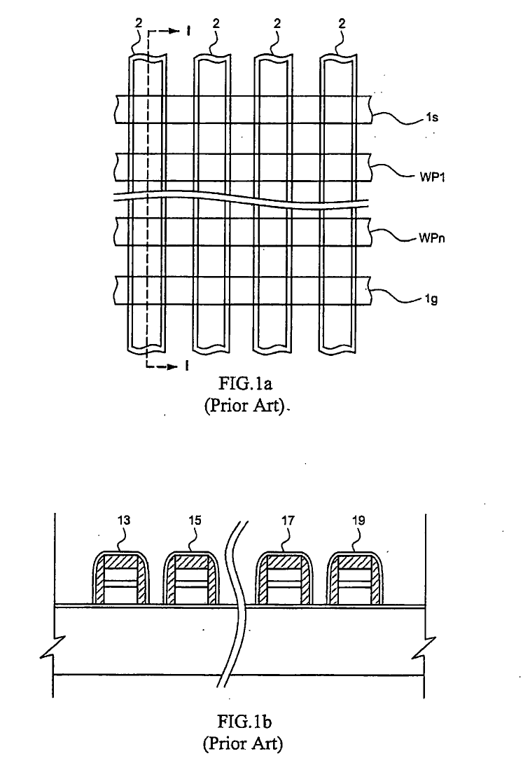

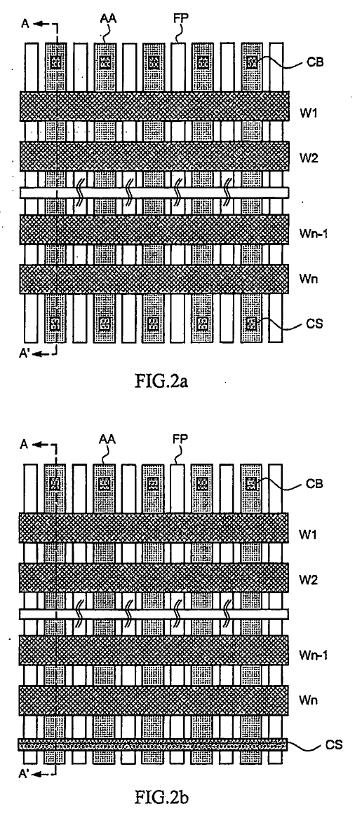

In the prior arts as illustrated in FIG. 1A and FIG. 1B, layouts such as the two selection line patterns, 1s and 1g, define the two selection transistors 13 and 19. With a self-aligned process of the present invention, a poly spacer is formed to substitute the selection transistors. This means that at least two selection line patterns can be removed from the fabricating process. Moreover, since the poly spacer is formed by a self-aligned process, the precision requirement for the manufacturing machine, such as a stepper, may be downgraded. Thus, the manufacturing cost for the present invention is much lower than that of the prior arts.

In addition, for a chip with a NAND flash memory cell array, the higher aspect ratio provided by the present invention is especially helpful in increasing the component density of the chip.

With the NAND flash memory cell array and the self-aligned process, fewer Critical Dimension (“CD”) losses and overlay will occur in a lithography process, hence increasing the stability of the fabricating procedures.

The embodiments described herein are meant to be illustrative only. Many variations, modifications, additions and improvements of the embodiments described are possible. For example, plural instances may be provided for the components described herein as a single instance. Additionally, structures and functionalities presented as separate components in the exemplary configurations may be implemented as a combined structure or component. These and other variations, modifications, additions and improvements will still fall within the scope of the invention as defined in the claims that follow.

What is claimed:

1. A NAND flash memory cell array, comprising:
a substrate with an active area;
a plurality of cells arranged in a row on said active area;
a first barrier layer covering said plurality of cells and said active area around each end of the row;
a first oxide deposited to fill a gap between said plurality of cells;
an oxide spacer formed along the sidewall of a cell located at each end of the row; and
a poly spacer formed on said oxide spacer acting as a selection gate for driving the row of cells.

2. The NAND flash memory cell array of claim 1, further comprising an implantation area formed by implanting predetermined ions into said active area around each end of the row.

3. The NAND flash memory cell array of claim 1, further comprising an oxide layer deposited on said poly spacer, said oxide spacer, said partial first barrier layer and said first oxide.

4. The NAND flash memory cell array of claim 3, further comprising a second barrier layer deposited on said oxide layer.

5. The NAND flash memory cell array of claim 4, further comprising an interlayer dielectric layer deposited on said second barrier layer and on said active area around each end of the row.

6. The NAND flash memory cell array of claim 4, further comprising a contact plug formed by depositing a plug material on an opening at each end of the row and planalizing the plug material by using a CMP process.

7. The NAND flash memory cell array of claim 6, further comprising a metal line formed at each end of the row.

8. The NAND flash memory cell array of claim 1, wherein the aspect ratio for said gap between said plurality of cells is about 1.8 to 3.2.

9. The NAND flash memory cell array of claim 1, wherein said first barrier layer is made of nitride or thin oxynitride.

10. The NAND flash memory cell array of claim 4, wherein both said first barrier layer and said second barrier layer are made of nitride or thin oxynitride.

11. A process for fabricating a NAND flash memory cell array, comprising the steps of:
forming a plurality of cells arranged in a row on an active area of a substrate;
depositing a first barrier layer covering said plurality of cells and said active area around each end of the row;
depositing a first oxide to fill a gap between said plurality of cells;
forming an oxide spacer along the sidewall of a cell located at each end of the row; and
forming a poly spacer on said oxide spacer.

12. The process of claim 11, after the step of forming said oxide spacer along the sidewall of a cell located at each end of the row, further comprising a step of stripping a portion of said first barrier layer and implanting predetermined ions into said active area around each end of the row.

13. The process of claim 11, after the step of forming said poly spacer on said oxide spacer, further comprising a step of depositing a second oxide over said substrate.

14. The process of claim 13, after the step of depositing said second oxide over the substrate, further comprising a step of forming a second barrier layer on said second oxide.

15. The process of claim 14, after the step of forming said second barrier layer on said second oxide, further comprising a step of depositing an interlayer dielectric layer on said substrate.

16. The process of claim 15, after the step of depositing said interlayer dielectric layer on said substrate, further comprising a step of forming a contact plug at each end of the row.

17. The process of claim 16, after the step of forming said contact plug at each end of the row, further comprising a step of forming a metal line on said contact plug.
